(19) United States
(12) Patent Application Publication
(10) Pub. No.: US 2007/0000686 A1
(43) Pub. Date: Jan. 4, 2007

(54) System, method and apparatus for routing signals from an integrated circuit using thickfilm and printed circuit interconnects

(76) Inventor: Peter Joseph Martinez, Colorado Springs, CO (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/170,330

(22) Filed: Jun. 29, 2005

(51) Int. Cl. H05K 7/06; H05K 1/18

(52) U.S. Cl. 174/255; 174/260; 361/764

(57) ABSTRACT

A package is disclosed for routing high frequency signals and low frequency signals between an integrated circuit device and other components. A package includes a thickfilm substrate having thickfilm interconnects, and a printed circuit board having printed circuit interconnects. A microcircuit system is disclosed for routing high frequency signals and low frequency signals. A microcircuit system comprises an integrated circuit device, a microcircuit package having a thickfilm substrate and a printed circuit board, high frequency connectors in attachment with the thickfilm interconnects, and low frequency connectors in attachment with the printed circuit interconnects. A method for routing high frequency signals and low frequency signals is disclosed. One method includes attaching low frequency portions of an integrated circuit device, printed circuit interconnects, and other components together, and attaching high frequency portions of the integrated circuit device, thickfilm interconnects, and other components together.

### BACKGROUND

Ceramic substrates having thickfilm interconnects are generally advantageous for the transmission of high frequency signals, such as signals in the radio frequency (RF) range, especially in conjunction with KQ material technology. One current disadvantage of thickfilm interconnects is the high cost of the thickfilm material per unit area.

A printed circuit board substrate with printed circuit interconnects is generally of lower cost per unit area than a thickfilm substrate with KQ material interconnects. However, the construction of printed circuit interconnects is generally only suitable for lower frequency signals, such as signals approaching direct current (DC). While some special substrates can achieve relatively high frequencies, these substrates will only transmit frequencies lower than non-organic substrates.

Most microcircuit package designs require the transmission of electrical signals at both high frequency and low frequency. However, if a particular design requires high frequency signals, the low frequency signals are also transmitted through the thickfilm circuit. This configuration requires thickfilm interconnects for the low frequency, i.e. DC signals, which in turn increases the cost of the package.

### SUMMARY OF THE INVENTION

In one embodiment, there is provided a package for routing signals from an integrated circuit, comprising a thickfilm substrate forming a first layer of the package, the thickfilm substrate having a set of thickfilm interconnects thereon, with at least some of the thickfilm interconnects having i) first ends positioned for electrical connection with the integrated circuit, and ii) second ends positioned for electrical connection with another level of interconnect; and a printed circuit board forming a second layer of the package, the printed circuit board having a set of printed circuit interconnects thereon, with at least some of the printed circuit interconnects having i) first ends positioned for electrical for electrical connection with the integrated circuit, and ii) second ends positioned for electrical connection with another level of interconnect.

In another embodiment, there is provided a system for routing signals from an integrated circuit, comprising an integrated circuit device configured for electrical connection with other components so as to transmit the high frequency signals and the low frequency signals therebetween; a package for routing signals from an integrated circuit, comprising a thickfilm substrate forming a first layer of the package, the thickfilm substrate having a set of thickfilm interconnects thereon, with at least some of the thickfilm interconnects having i) first ends positioned for electrical connection with the integrated circuit, and ii) second ends positioned for electrical connection with another level of interconnect; and a printed circuit board forming a second layer of the package, the printed circuit board having a set of printed circuit interconnects thereon, with at least some of the printed circuit interconnects having i) first ends positioned for electrical for electrical connection with the integrated circuit, and ii) second ends positioned for electrical connection with another level of interconnect; and a first set of connectors and a second set of connectors, the first set of connectors in electrical connection with the thickfilm interconnects and the integrated circuit, and the second set of connectors in electrical connection with the printed circuit interconnects and the integrated circuit.

In another embodiment, there is provided a method for routing high frequency signals and low frequency signals between an integrated circuit device and other components, the method comprising providing a package having a thickfilm substrate and a printed circuit board in attachment with one another; attaching portions of the integrated circuit device configured to route high frequency signals and a set of thickfilm interconnects disposed on the thickfilm substrate in electrical connection with one another; attaching portions of the integrated circuit device configured to route low frequency signals and a set of printed circuit interconnects of the printed circuit board in electrical connection with one another; attaching portions of the other components configured to route high frequency signals and the thickfilm interconnects disposed on the thickfilm substrate in electrical connection with one another; and attaching portions of the other components configured to route high frequency signals and the printed circuit interconnects of the printed circuit board in electrical connection with one another.

Other embodiments are also disclosed.

### BRIEF DESCRIPTION OF THE DRAWINGS

Illustrative embodiments of the invention are illustrated in the drawings, in which:

FIG. 1 illustrates a set of thickfilm interconnects mounted on a package substrate;

FIG. 2 illustrates an integrated circuit device (IC) mounted in a center opening of the package base shown in FIG. 1, with the integrated circuit device disposed between the thickfilm interconnects mounted on the package substrate;

FIG. 3 illustrates an assembly of a package including a printed circuit board (PC board) in connection with the package substrate of FIG. 1, in which the package substrate and the printed circuit board are attached to one another using an adhesive;

FIG. 4 illustrates a layer of adhesive attaching the package substrate and the printed circuit board to one another;

FIG. 5 illustrates a portion of the microcircuit package of FIG. 3 in which the integrated circuit device is in electrical connection with the thickfilm interconnects using high frequency wire bonds and with the printed circuit interconnects using low frequency wire bonds;

FIG. 6A illustrates a microcircuit package having a set of RF connectors that extend from the package perpendicular to, and in electrical connection with, the set of thickfilm interconnects of the substrate;

FIG. 6B illustrates the reverse side of the package shown in FIG. 6A, with a ball grid array extending from, and in electrical connection with, the printed circuit interconnects of the printed circuit board;

FIG. 7 illustrates a package with high frequency, a set of RF connectors that extend from the package parallel to, and in electrical connection with, the set of thickfilm interconnects of the substrate and in connection with a machined package base, and a pair of low frequency, surface mount connector devices in electrical connection with the printed circuit interconnects of the printed circuit board, and a flat lid covering the integrated circuit device disposed within the opening of the printed circuit board; and

FIG. 8 illustrates a package with high frequency, edge launch RF connectors in electrical connection with the thickfilm interconnects of the thickfilm ceramic substrate and in connection with a simple package base, and and a flat lid covering the integrated circuit device disposed within the opening of the printed circuit board.

### DETAILED DESCRIPTION OF AN EMBODIMENT

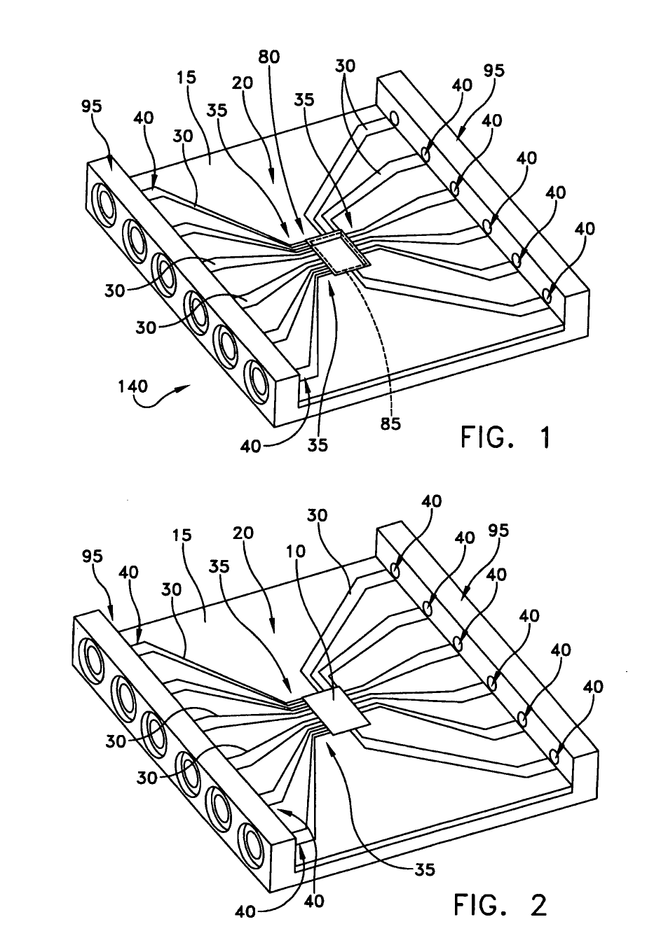

In an embodiment, a package 5 (FIG. 1) is provided for high frequency signals and low frequency signals to another level of interconnect. For example, radio frequency (RF) signals are one type of high frequency signal and direct current (DC) signals are one type of low frequency signal. These high frequency signals and low frequency signals are routed from an integrated circuit device 10 to other components through package 5.

Referring to FIGS. 1-5, there is shown package 5 for routing high frequency signals and low frequency signals between integrated circuit device 10 and other components. A thickfilm substrate 15 forms a first layer of package 5. Thickfilm substrate 15 may include, but is not limited to, a ceramic material, a glass material, or metal coated with a dielectric material. For the purposes of illustration hereinbelow, thickfilm substrate is referred to as a thickfilm ceramic substrate. Thickfilm ceramic substrate 15 has a first side 20 and a second side 25 in opposition to one another. A set of thickfilm interconnects 30 are disposed on first side 20 of thickfilm ceramic substrate 15. Each one of thickfilm interconnects 30 have a first end 35 and a second end 40. First end 35 of each one of thickfilm interconnects 30 is configured for electrical connection with integrated circuit device 10. Second end 40 of each one of thickfilm interconnects 30 is configured for electrical connection with another level of interconnect located away from integrated circuit device 10. In an embodiment, thickfilm interconnects 30 are configured to transmit high frequency signals between integrated circuit device 10 and other components. Optionally, both high frequency signals and low frequency signals may be transmitted through thickfilm interconnects 30. However, in an embodiment, the amount of material used to form thickfilm interconnects 30 is reduced inasmuch as at least some low frequency signals are not transferred through the thickfilm interconnects 30.

A printed circuit board 45 forms a second layer of microcircuit package 5. Printed circuit board 45 has a first side 50 and a second side 55. A set of printed circuit interconnects 60 are disposed on first side 50 of printed circuit board 45. Each one of printed circuit interconnects 60 having a first end 65 and a second end 70. First end 65 of each one of printed circuit interconnects 60 is configured for electrical connection with integrated circuit device 10. Second end 70 of each one of printed circuit interconnects 60 are configured for electrical connection with another level of interconnect located away from integrated circuit device 10. Printed circuit interconnects 60 are configured to transmit low frequency signals between integrated circuit device 10 and the other components.

In an embodiment, package 5 is constructed with first side 20 of thickfilm ceramic substrate 15 and second side 55 of printed circuit board 45 disposed toward one another. An adhesive 75 attaches first side 20 of thickfilm ceramic substrate 15 and second side of printed circuit board 45 to one another. Adhesive 75 may be a dielectric material.

In an embodiment, portions of thickfilm interconnects 30 and printed circuit interconnects 60 are in electrical connection with one another. Adhesive layer 75 between printed circuit board 45 and KQ thickfilm substrate 15 may be patterned to provide areas of conductive connection between interconnects 60 of printed circuit board 45 and interconnects 30 of thickfilm substrate 15.

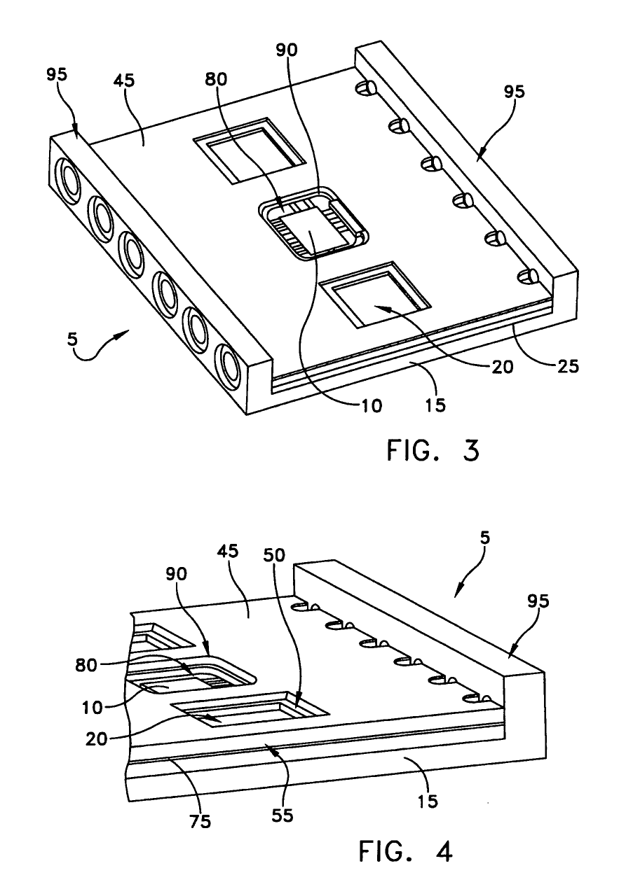

Looking at FIGS. 3-5 and 6B, and in an embodiment, first ends 35 of thickfilm interconnects 30 are disposed adjacent a center portion 80 of thickfilm ceramic substrate 15. First ends 35 of thickfilm interconnects 60 form an opening 85 therebetween. Opening 85 has a given area sized to receive integrated circuit device 10 therein, although in other embodiments opening 85 need not exist as the integrated circuit device 10 may be applied directly onto the thickfilm substrate 15. Printed circuit board 45 forms an opening 90 therein. Opening 90 of printed circuit board 45 has a given area sized to receive integrated circuit device 10 therethrough. Second ends 35 of thickfilm interconnects 30 are disposed adjacent an outer portion 95 of thickfilm ceramic substrate 15. Opening 90 of printed circuit board 45 has a greater width than opening 85 formed between first ends 35 of the thickfilm interconnects 30. In an embodiment, each opening 85 for integrated circuit 10 in thickfilm interconnects 30 is smaller than opening 90 in printed circuit board 45. This configuration forms a “terraced” structure around integrated circuit device 10.

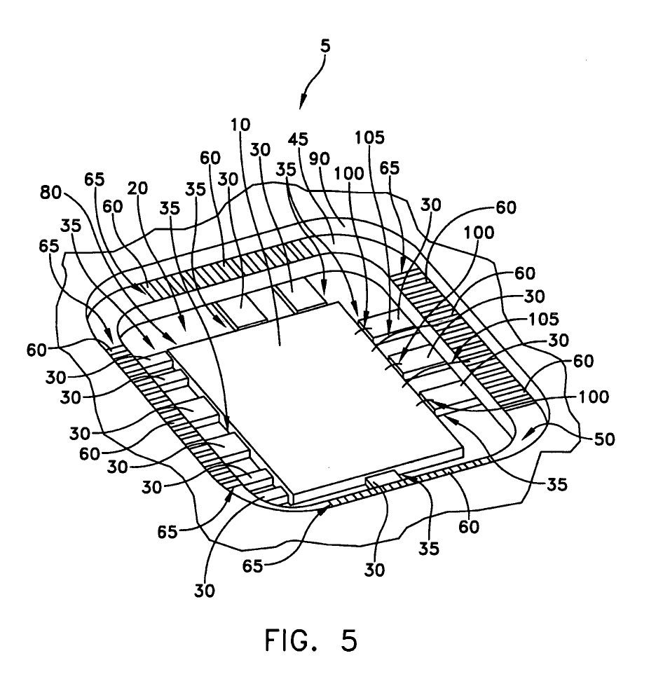

Referring to FIG. 5, and in an embodiment, a first set of wire bonds 100 are configured to transmit high frequency signals between integrated circuit device 10 and thickfilm interconnects 30. A second set of wire bonds 105 are configured to connect the low frequency signals between integrated circuit device 10 and printed circuit interconnects 60. In this configuration, each one of first set of wire bonds 100 anchored to thickfilm interconnects 30 are disposed further from integrated circuit device 10 than each one of second set of wire bonds 105 anchored to printed circuit interconnects 60. In an embodiment, one or both of first set of wire bonds 100 and second set of wire bonds 105 may include a single wire bond.

In an embodiment, thickfilm interconnects 30 are in electrical connection with a first set of portions across integrated circuit device 10 so as to transmit high frequency signals therethrough. Printed circuit interconnects 60 are in electrical connection with a second set of portions across integrated circuit device 10 so as to transmit the high frequency signals therethrough.

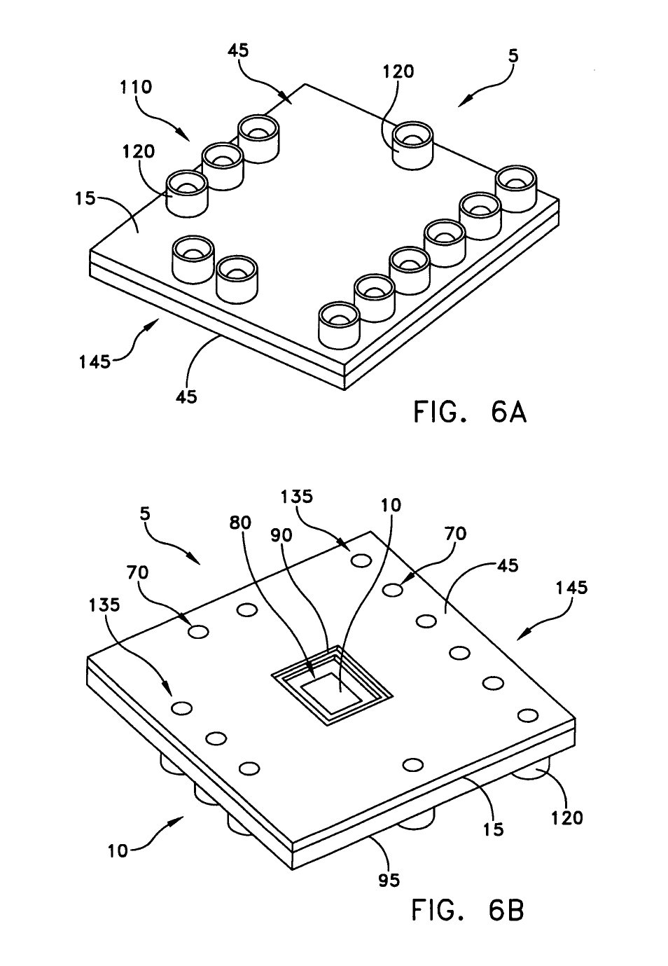

Looking now at FIGS. 6A, 6B, 7 and 8, there are shown a first set of connectors 110 and a second set of connectors 115. First set of connections 110 are in electrical connection with second end 40 of thickfilm interconnects 30 and second set of connectors 115 are in electrical connection with second end 70 of printed circuit interconnects 60.

In FIGS. 6A and 6B, there is shown a set of RF connectors 120 that extend from package 5 perpendicular to the set of thickfilm interconnects 30, and RF connectors 120 are provided as first set of connectors 110.

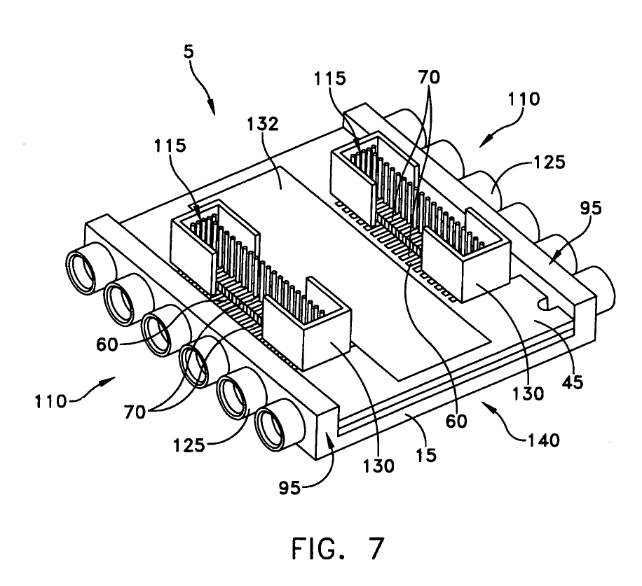

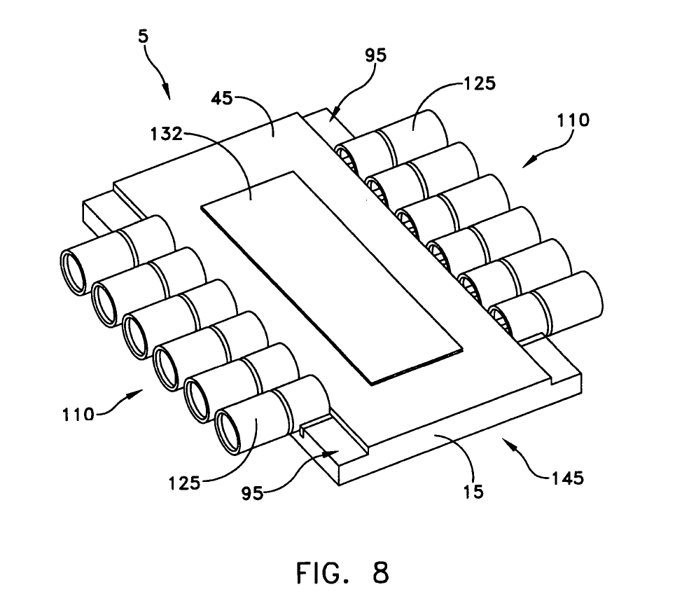

In FIGS. 7 and 8, there is shown a set of RF connectors 125 that extend from package 5 perpendicular to the set of thickfilm interconnects 30, and RF connectors are provided as first set of connectors 110.

In FIG. 7, there is shown a surface mount connector 130 on each side of printed circuit board 45. In an embodiment, surface mount connectors 130 are provided as second set of connectors 115. A flat lid 132 may be provided to cover integrated circuit device 10 disposed within opening 90 of printed circuit board 45.

In FIG. 6B, there is shown a ball grid array 135, which is provided as second set of connectors 115.

In FIG. 8, a ball grid array (not shown) may be provided adjacent to flat lid 132 covering integrated circuit device 10 disposed within opening 90 of printed circuit board 45.

In general, the size of KQ thickfilm substrate 15 may be minimized by selecting properly sized RF connectors 120 or RF connectors 125. In other words, a smaller connector 120 or 125 allows the use of a smaller KQ thickfilm substrate 15.

Package 5 may be built atop a base package/heat spreader. However, package 5 may include only thickfilm substrate 15 and printed circuit board 45.

In an embodiment, there is provided a method for routing high frequency signals and low frequency signals between integrated circuit device 10 and other components. Generally, the method includes providing package 5 having thickfilm ceramic substrate 15 and printed circuit board 45 in attachment with one another. Portions of integrated circuit device 10 configured to route high frequency signals and thickfilm interconnects 30 disposed on thickfilm substrate 15 are attached in electrical connection with one another. Portions of integrated circuit device 10 configured to route low frequency signals and printed circuit interconnects 60 of printed circuit board 45 are attached in electrical connection with one another. Portions of the other components configured to route high frequency signals and thickfilm interconnects 30 disposed on thickfilm substrate 15 are attached in electrical connection with one another. Portions of the other components configured to route high frequency signals and printed circuit board interconnects 60 of printed circuit board 45 are attached in electrical connection with one another.

Some advantages that can be realized using the packages described herein include, but are not limited to, lower cost of KQ thickfilm substrate 15 due to the reduction in area of thickfilm interconnect 30, lower cost of packaging 5 due to smaller and simpler packaging, and greater routing densities due to the multi-layer structure of printed circuit board 45 in conjunction with thickfilm substrate 30.

What is claimed is:

1. A package for routing signals from an integrated circuit, comprising:
a thickfilm substrate forming a first layer of the package, the thickfilm substrate having a set of thickfilm interconnects thereon, with at least some of the thickfilm interconnects having i) first ends positioned for electrical connection with the integrated circuit, and ii) second ends positioned for electrical connection with another level of interconnect; and
a printed circuit board forming a second layer of the package, the printed circuit board having a set of printed circuit interconnects thereon, with at least some of the printed circuit interconnects having i) first ends positioned for electrical for electrical connection with the integrated circuit, and ii) second ends positioned for electrical connection with another level of interconnect.

2. The package of claim 1, wherein the thickfilm interconnects are formed on a side of the thickfilm substrate oriented toward the printed circuit board.

3. The package of claim 1, further comprising an adhesive that attaches a first side of the thickfilm substrate to a first side of the printed circuit board.

4. The package of claim 3, wherein the adhesive comprises dielectric characteristics.

5. The package of claim 1, wherein portions of the thickfilm interconnects and the printed circuit interconnects are in electrical connection with one another.

6. The package of claim 1, wherein the first ends of the at least some thickfilm interconnects are positioned adjacent a portion of the thickfilm substrate defining a receiving area for the integrated circuit.

7. The package of claim 6, wherein the second ends of the at least some thickfilm interconnects are positioned adjacent an outer portion of the thickfilm substrate.

8. The package of claim 6, wherein the printed circuit board has an opening therein, the opening being sized to receive the integrated circuit therethrough.

9. The package of claim 8, wherein the opening of the printed circuit board has a dimension that is great enough to reveal, through the opening, at least a portion of at least one of the first ends of the thickfilm interconnects.

10. The package of claim 9, further comprising:
the integrated circuit;
a first set of wire bonds configured to route high frequency signals between the integrated circuit and the thickfilm interconnects; and
a second set of wire bonds configured to route low frequency signals between the integrated circuit and the printed circuit interconnects.

11. The package of claim 1, further comprising:
the integrated circuit;
a first set of wire bonds configured to route high frequency signals between the integrated circuit and the thickfilm interconnects; and
a second set of wire bonds configured to route low frequency signals between the integrated circuit and the printed circuit interconnects.

12. The package of claim 1, wherein the thickfilm substrate comprises a ceramic substrate.

13. The package of claim 1, further comprising:
a first set of connectors in electrical connection with the second ends of at least some of the thickfilm interconnects; and
a second set of connectors in electrical connection with the second ends of at least some of the printed circuit interconnects.

14. The package of claim 13, wherein the first set of connectors comprises a set of RF connectors that extend from the package perpendicular to the set of thickfilm interconnects.

15. The package of claim 13, wherein the first set of connectors comprises a set of RF connectors that extend from the package parallel to the set of thickfilm interconnects.

16. The package of claim 13, wherein the second set of connectors comprises at least one edge connector.

17. The package of claim 13, wherein the second set of connectors comprises a ball grid array.

18. A system for routing signals from an integrated circuit, comprising:
an integrated circuit device configured for electrical connection with other components so as to transmit the high frequency signals and the low frequency signals therebetween;
a package for routing signals from an integrated circuit, comprising:
a thickfilm substrate forming a first layer of the package, the thickfilm substrate having a set of thickfilm interconnects thereon, with at least some of the thickfilm interconnects having i) first ends positioned for electrical connection with the integrated circuit, and ii) second ends positioned for electrical connection with another level of interconnect; and
a printed circuit board forming a second layer of the package, the printed circuit board having a set of printed circuit interconnects thereon, with at least some of the printed circuit interconnects having i) first ends positioned for electrical for electrical connection with the integrated circuit, and ii) second ends positioned for electrical connection with another level of interconnect; and
a first set of connectors and a second set of connectors, the first set of connectors in electrical connection with the thickfilm interconnects and the integrated circuit, and the second set of connectors in electrical connection with the printed circuit interconnects and the integrated circuit.

19. The system of claim 18, wherein the first set of connectors comprises a set of RF connectors that extend from the package perpendicular to the set of thickfilm interconnects.

20. The system of claim 18, wherein the second set of connectors comprises an edge connector.

21. The system of claim 18, wherein the second set of connectors comprises a ball grid array.

22. A method for routing high frequency signals and low frequency signals between an integrated circuit device and other components, the method comprising:
providing a package having a thickfilm substrate and a printed circuit board in attachment with one another;
attaching portions of the integrated circuit device configured to route high frequency signals and a set of thickfilm interconnects disposed on the thickfilm substrate in electrical connection with one another;
attaching portions of the integrated circuit device configured to route low frequency signals and a set of printed circuit interconnects of the printed circuit board in electrical connection with one another;
attaching portions of the other components configured to route high frequency signals and the thickfilm interconnects disposed on the thickfilm substrate in electrical connection with one another; and
attaching portions of the other components configured to route low frequency signals and the printed circuit interconnects of the printed circuit board in electrical connection with one another.
